(19) United States
(12) Patent Application Publication
(10) Pub. No.: US 2014/0210460 A1
(43) Pub. Date: Jul. 31, 2014

(54) CONTACTLESS ELECTRIC METER READING DEVICES

(71) Applicant: Hampden Kuhns, Reno, NV (US)

(72) Inventor: Hampden Kuhns, Reno, NV (US)

(21) Appl. No.: 14/169,047

(22) Filed: Jan. 30, 2014

Related U.S. Application Data
(60) Provisional application No. 61/758,284, filed on Jan. 30, 2013.

(51) Int. Cl. G01R 21/00; G01R 21/08

(52) U.S. Cl. CPC G01R 21/00; G01R 21/08
USPC 324/244

(57) ABSTRACT

This application concerns devices and methods for measuring power flow through an electric meter without a direct electrical connection to the current-carrying conductors of the electric meter. In one representative embodiment, a contactless electric meter sensor comprises an annular member configured to be disposed around an electric meter, and one or more magnetic field sensors mounted on the annular member. The one or more magnetic field sensors can be configured to sense one or more magnetic fields generated by one or more current-carrying conductors passing through the electric meter.

### CROSS REFERENCE TO RELATED APPLICATION

This application claims the benefit of the earlier filing date of U.S. Provisional Application No. 61/758,284, filed on Jan. 30, 2013, which is incorporated herein by reference in its entirety.

### FIELD

This application concerns devices and methods for measuring power flow through an electric meter without a direct electrical connection to the current-carrying conductors of the electric meter.

### BACKGROUND

Electrical smart meters largely serve the needs of utilities by enabling remote reading and shutoff as well as time of use billing. Benefits to ratepayers have been limited in that users may be able to view their energy consumption at the same rate as the utility company (generally every 15 minutes or longer). Higher frequency power consumption data is useful to ratepayers since they can use this information to determine what loads are responsible for their largest energy expense. Therefore, high temporal resolution power monitoring systems that can be installed by a lay person are desirable.

### SUMMARY

This application concerns devices and methods for measuring power flow through an electric meter. In one representative embodiment, a contactless electric meter sensor comprises an annular member configured to be disposed around an electric meter, and one or more magnetic field sensors mounted on the annular member. The one or more magnetic field sensors can be configured to sense one or more magnetic fields generated by one or more current-carrying conductors passing through the electric meter.

In another representative embodiment, a method of measuring electric power usage comprises positioning a contactless electric meter sensor around the exterior of an electric meter, the contactless electric meter sensor comprising one or more magnetic field sensors mounted on an annular member, and sensing the strength of one or more magnetic fields generated by one or more current-carrying conductors located within the electric meter. The method can further comprise calculating the electric power flowing through the electric meter based at least in part on the strength of the one or more magnetic fields.

In another representative embodiment, a system for measuring power usage at an electric meter comprises an annular member disposed around the electric meter, one or more magnetic field sensors mounted on the annular member, and a signal processing module in communication with the one or more magnetic field sensors.

The foregoing and other objects, features, and advantages of the invention will become more apparent from the following detailed description, which proceeds with reference to the accompanying figures.

### BRIEF DESCRIPTION OF THE DRAWINGS

FIGS. 1A-1E illustrate various embodiments of electric meters

FIG. 2 is a plan view of an electric meter sensor.

FIG. 3 is a plan view of an electric meter sensor disposed around an electric meter.

FIG. 4 is a perspective view of a handheld device measuring a magnetic field.

FIG. 5 is a perspective view of the handheld device measuring a magnetic field adjacent an electric meter.

### DETAILED DESCRIPTION

As used in this application and in the claims, the singular forms “a,” “an,” and “the” include the plural forms unless the context clearly dictates otherwise. Additionally, the term “includes” means “comprises.” Further, the terms “coupled” and “associated” generally means electrically, electromagnetically, and/or physically (e.g., mechanically or chemically) coupled or linked and does not exclude the presence of intermediate elements between the coupled or associated items.

Although the operations of exemplary embodiments of the disclosed method may be described in a particular, sequential order for convenient presentation, it should be understood that disclosed embodiments can encompass an order of operations other than the particular, sequential order disclosed. For example, operations described sequentially may in some cases be rearranged or performed concurrently. Further, descriptions and disclosures provided in association with one particular embodiment are not limited to that embodiment, and may be applied to any embodiment disclosed.

Moreover, for the sake of simplicity, the attached figures may not show the various ways (readily discernable, based on this disclosure, by one of ordinary skill in the art) in which the disclosed system, method, and apparatus can be used in combination with other systems, methods, and apparatuses. Additionally, the description sometimes uses terms such as “produce” and “provide” to describe the disclosed method. These terms are high-level abstractions of the actual operations that can be performed. The actual operations that correspond to these terms can vary depending on the particular implementation and are, based on this disclosure, readily discernible by one of ordinary skill in the art.

As used herein, the term “contactless” refers to a spaced-apart relationship between two elements where there is no contact between the two elements. For example, “contactless” can mean that there is no physical contact between two elements.

High temporal resolution measurements (i.e., greater than 1 Hz) can be useful for performing advanced signal processing on electrical signals to assess energy end use, such as with Non-Intrusive Load Monitoring (NILM). NILM applications can itemize energy bills to major loads using signal processing on the electrical current, voltage, and/or energy signals. Technologies to acquire these measurements often require an electrician to install current and voltage sensors different from the electric meter. Torriodal current sensors, such as current transformers and Rogowski coils, must be installed around the current carrying wires serving the loads. In many cases, the only access point to place these sensors around the wires serving the loads is behind the deadfront panel of a circuit breaker panel. Working with the deadfront panel removed can expose the installer to risk of electric shock through contact with energized bus bars. The need for professional installation has limited the application of sub-metering to environments where energy expense is large or critical to reliable systems operation.

Embodiments of electric meter sensors disclosed herein can measure magnetic and electric fields directly surrounding an electric meter and can substantially reduce the calibration variability associated with positioning sensors at specific distances from lines inside circuit breaker panels. In one embodiment, magnetic field sensors (e.g. anisotropic magnetoresistive sensors, geometrical magnetoresistive sensors, and hall effect sensors) are mounted on a band that is placed around the outside of a socket based electrical meter. A series of magnetic field sensors can be used to monitor signals proportional to the current passing through each of the current carrying connections inside the meter. Each measurement of the magnetic field is affected by all conductors in the meter as well as other interfering sources, such as the earth's magnetic field. In a vacuum, the field strength decreases proportional to the inverse of the square of the distance from the current carrying conductor.

The following method can be used to filter out interfering signals from signals associated with the currents flowing through the electric meter. The current on individual current-carrying conductors in the meter is determined by positioning a plurality magnetic and electric field sensors around the outside of the electric meter. Numerical regression and optimization methods can be used to isolate signals from the main currents of interest from other interfering magnetic fields. Prior knowledge of the number of electrical phases passing through the meter determines the optimization functions that can be used to extract the fundamental current measurements.

The instantaneous magnetic field at each sensor B, is represented as a sum of field components associated with each current in the meter. In a 3-phase system, the magnetic field components can include I₁ on phase 1, I₂ on phase 2, I₃ on phase 3, Iₙₑᵤₜᵣₐₗ and the Background field. Thus, Bᵢ can be represented by the following equation:

Bᵢ=αᵢI₁+βᵢI₂+γᵢI₃+Background

Properties of AC power systems can be used to constrain the solution for the unknown parameters α, β, γ and Background. Constraints include: (1) the time averaged current on an AC line is 0 A; (2) in a split phase setting with two voltage lines, the two voltages and currents are approximately 180 degrees out of phase with each other; (3) in a 3-phase system, the voltages and currents are approximately 120 degrees out of phase with each other; and (4) the current has a primary frequency at the voltage frequency of the AC line. Other constraints about the proximity of each phase of the current carrying lines to perimeter of the electric meter provide additional information to mathematically solve for the unknown terms α, β, γ and Background. For each sensor, the terms α, β, and γ are fixed because their physical position on the side of the meter does not change. The background interference can change with time and will have a similar influence on each sensor. Accuracy of solving these terms is improved by measuring the electric or magnetic fields at more points than there are unknown terms. This creates an over determined set of equations so that numerical techniques can resolve the unknown parameters. In turn, I₁, I₂, and I₃ can be solved for using a linear equation of all sensed values. This approach captures the temporal dependence of the magnetic field sensors on each current. Additional measurements of power from monthly meter readings or current sensors are used to calibrate the conversion of multiply sensed magnetic fields into line current. For example I₁=a₁B₁+a₂B₂+a₃B₃+a₄B4 + . . .

In another embodiment the magnetic fields sensors can be combined with contactless voltage sensors, such as electric field sensors (e.g. capacitor-coupled and varactor), to produce electric field signals that are proportional to line voltage. In some embodiments, the contactless voltage sensor produces a signal that is proportional to the voltage in the line. In alternative embodiments, the raw signal is proportional to the rate of change in the voltage of the line. Signal conditioning to integrate the rate of signal change (by hardware or software methods) may be necessary to produce a signal that is directly proportional to the line voltage. Cross talk of the electric field from phase to phase and outside background electric field interference can be managed using the constrained optimization and regression technique described above to process the current from the magnetic field. Additional sensors mounted around the electric meter can be used to improve the accuracy of the line voltage measurements.

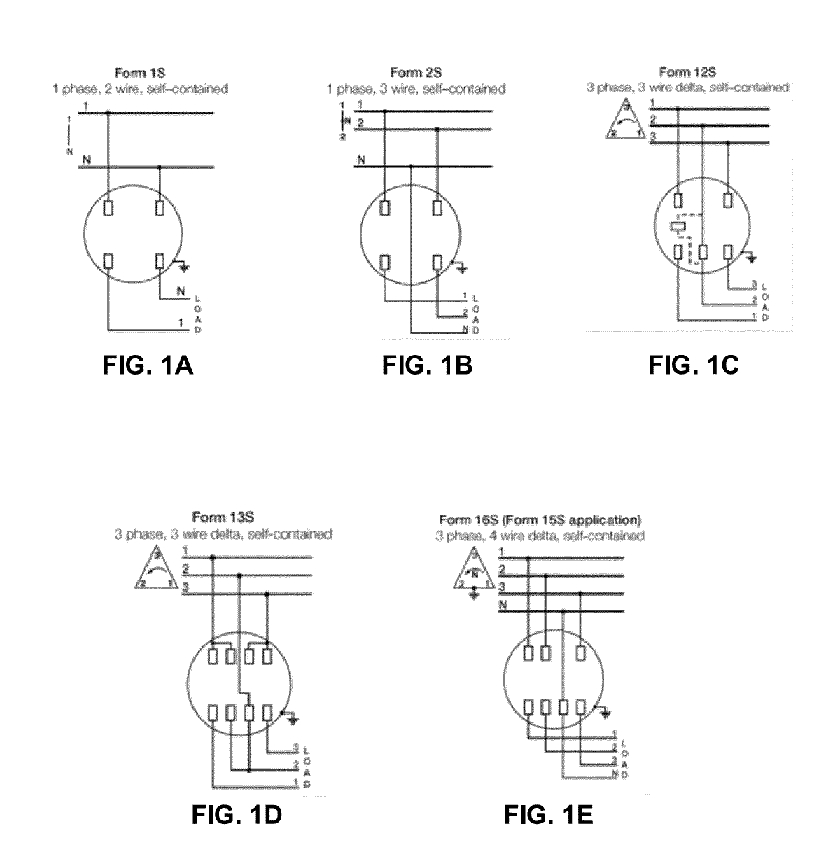

FIGS. 1A-1E illustrate a number of standardized configurations used for electric meters (e.g. Form 1S, 2S, 12S, 13S, 16S, 13A, 14A, and 16A). Based on this conformity of shapes and sizes, some embodiments may not require a field calibration step when the sensors are properly calibrated on any similar socket type electric meter. In some embodiments, calibrations can be performed by a user reading the electric power meter at two separate times and manually entering the measurements into a user interface connected to the electric meter sensor through a computer network. The difference in energy consumed between the two times is equal to the time integrated product of the inferred voltage and current. If only the magnetic field is measured on the perimeter of the electric meter, reference power can be estimated using the nominal service voltage. The process of calibration with the electric meter can reference the contactless measurements of the electric meter sensor with a certifiable standard at the installation site.

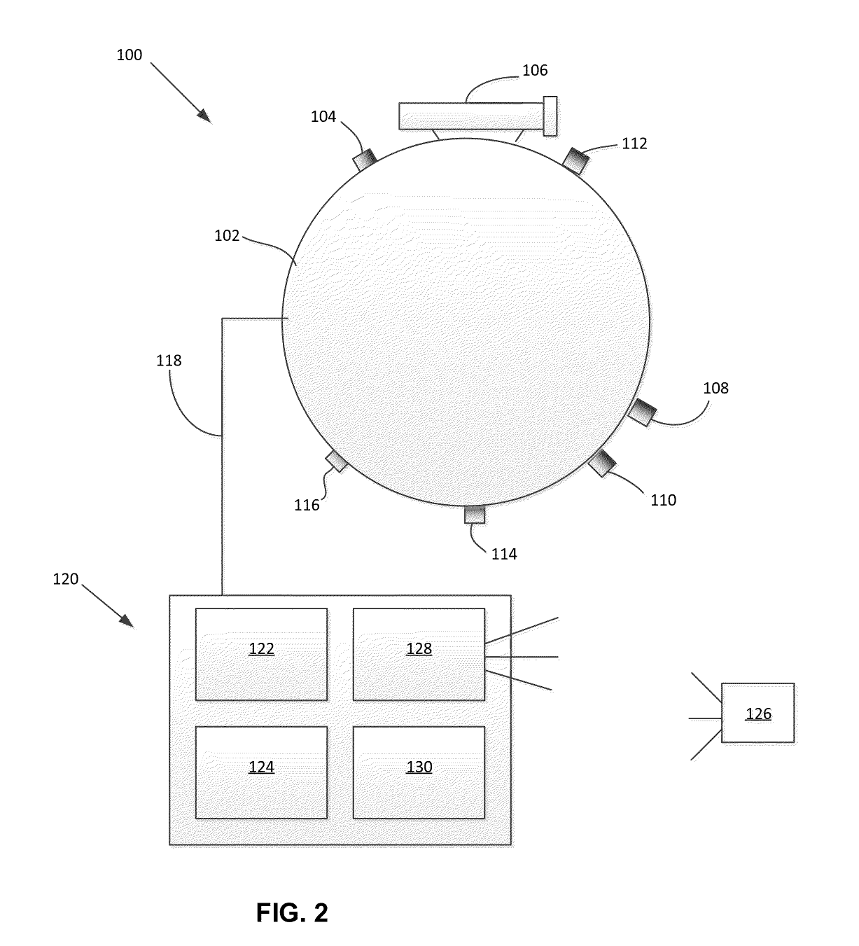

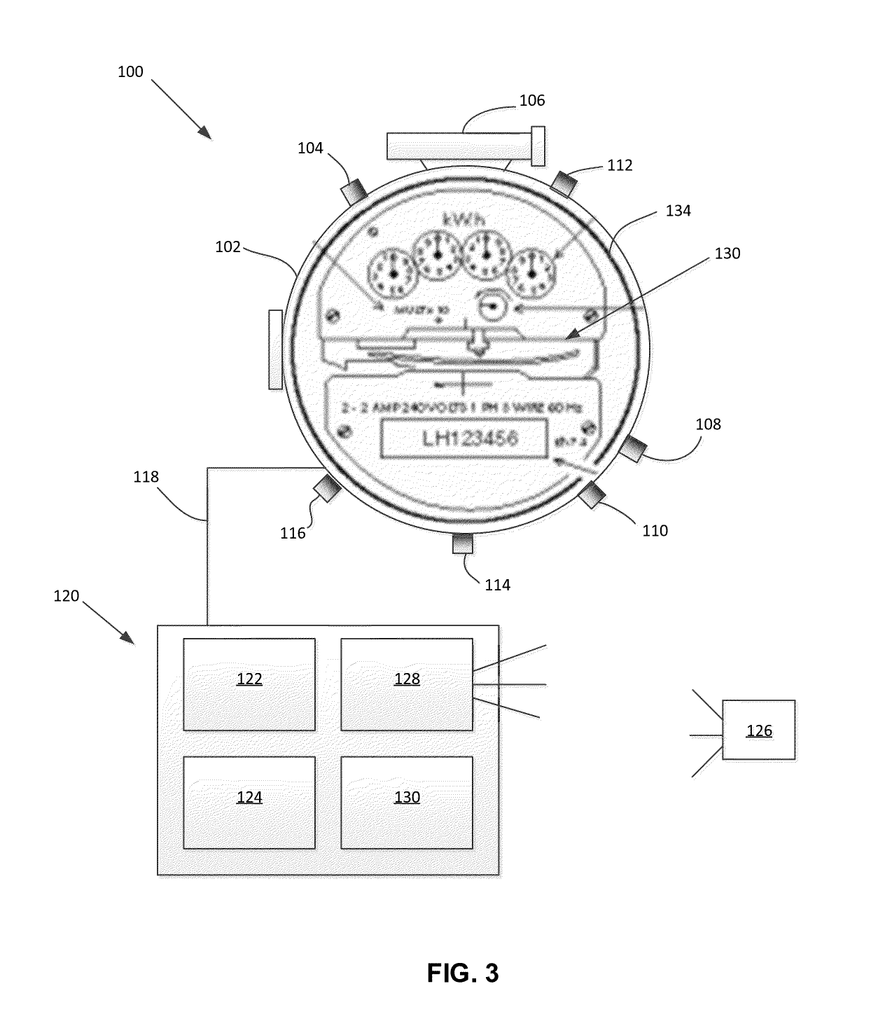

Referring to FIG. 2, an electric meter sensor 100 can comprise an annular member 102 configured to be disposed around an electric meter. The annular member 102 can comprise one or more magnetic field sensors 104 located around a perimeter of the annular member. In this manner, when the electric meter sensor 100 is disposed around an electric meter 132, the one or more magnet field sensors 104 can be situated around the enclosure 134 of the electric meter 132, as shown in FIG. 3. In some embodiments, the annular member 102 can include a clamp 106 for clamping the electric meter sensor 100 to the electric meter 132. In some embodiments, the clamp 106 can comprise a hose clamp drive system to tighten the ring around the electric meter 132. In alternative embodiments, the annular member 102 can comprise an elastic band such that the electric meter sensor 100 can be self-retaining when placed on the electric meter 132.

Signals from the magnetic field sensors 104 on the electric meter sensor 100 can be used to infer 1, 2, or 3 phases of electrical current service using tensor based signal isolation techniques. In some embodiments, the electric meter sensor 100 can further comprise a tunneling magnetoresistive sensor (TMR) 108 and/or geometric magnetoresistive (GMR) sensor 110 to increase signal fidelity. In this manner, the magnetic field can be measured in a way that does not require a reset strap, as is commonly required with anisotropic magnetoresistive sensors (AMR). In some embodiments, a magnetic field flux concentrator 112 can be used to increase the signal from adjacent mains and reduce interference from other mains or sources outside the electric meter 132 (e.g. nearby power lines or the earth's magnetic field).

Consistent placement of the magnetic field sensors 104 on the annular member 102 with respect to current carrying wires or socket fittings in the electric meter 132 can be important for producing reliable measurements of line current. Placement of one or more voltage sensors 114 can also be important for the accuracy of voltage. In some embodiments, the one or more voltage sensors 114 can be contactless voltage sensors, as described above. In some embodiments, a built-in spirit level 116 on the annular member 102 can be used to ensure that the annular member 102 is positioned in the same vertical orientation as the electric meter 132.

In some embodiments, the signals can be sent through an electrical lead 118 to a processor module 120 where the signals can be multiplexed and amplified by an amplifier 122, processed using the method described above to isolate the current and voltages on the mains by a processor 124. The processed signals can then be sent directly to a remote device 126 via a transmitter 128 for display to a user, or to additional devices for NIALM processing. In some embodiments, the electric meter sensor may be powered using an AC connection, solar panel, battery, or magnetic field energy scavenger 130 to perform the tasks of signal conditioning, processing, and wirelessly transmitting the measurements to a computer network or remote device such as the device 126.

In some embodiments, the magnetic field sensors can sense the magnetic fields with a sampling frequency higher than the fundamental frequency of the AC line (60 Hz or 50 Hz) so that signatures of the current waveform can be resolved with sufficient detail to distinguish individual loads. In some embodiments, the magnetic field sensors can be configured to sense the magnetic fields at a frequency of from about 1 Hz to about 10,000 Hz. In some embodiments, the magnetic field sensors can be configured to sense the magnetic fields at a frequency of from about 40 Hz to about 8,000 Hz.

This electric meter sensor 100 offers an advantage over contactless current and voltage sensing approaches installed in the circuit breaker panel since it is easier to install than a sensor mounted on the deadfront of a circuit breaker panel. The consistency of meter socket geometry enables isolation of up to 3 phases of AC mains passing through the meter. In the circuit breaker panel, distances to current carrying wires may vary due to specific circuit breaker design, wire orientation behind the deadfront, and proximity to interfering field sources. The distances of the sensors to the current-carrying conductors in the electric meter 132 is very similar from one meter to the next. This property allows the magnetic field sensors 104 and the voltage sensors 114 to be pre-calibrated to the line voltages and currents prior to deployment and thereby facilitate the installation. In this manner, each of the one or more magnetic field sensors 104 can be located a predetermined distance from the respective current-carrying conductors when the electric meter sensor 100 is installed on the electric meter 132. The predetermined distance can be equal

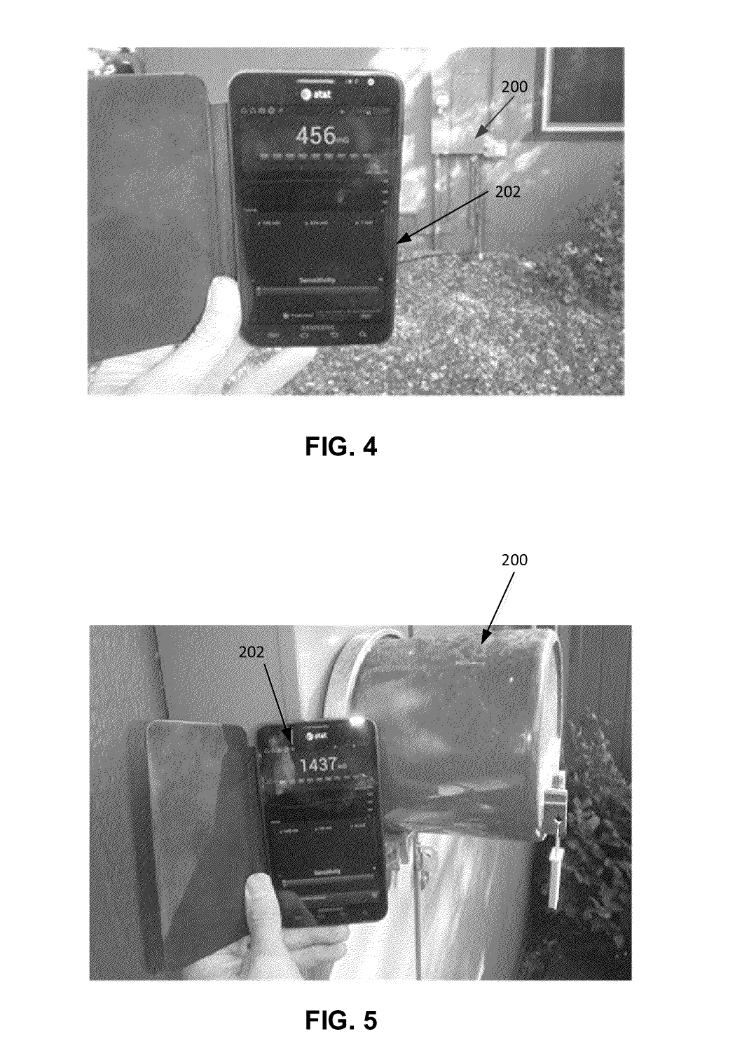

The ability to measure the magnetic field generated by current-carrying conductors in an electric meter 200 is shown in FIGS. 4 and 5. A handheld device 202 comprising a 3-dimensional magnetometer can measure a magnetic field strength and direction at about 10 Hz in terms of miliGauss (mG) in the x, y, and z directions.

When the handheld device 202 is located about 3 m away from the electric meter 200, the measured magnetic field is 456 mG, as shown in FIG. 4. When the handheld device 202 is placed adjacent to the electric meter 200 passing 30 Amps, the integrated magnetic field is 1437 mG, as shown in FIG. 5. The increase in field strength is due to the magnetic field of the AC current passing through the current-carrying conductors of the electric meter 200.

The electric meter sensor 100 can be useful for collecting high time resolution current and/or voltage measurements at an electric meter, and can be quickly, safely, and precisely installed by a user. The benefit of this approach is that the electric meter sensor 100 may be installed in less time, while reducing a user's exposure to the risk of electric shock.

In view of the many possible embodiments to which the principles of the disclosed invention may be applied, it should be recognized that the illustrated embodiments are only preferred examples of the invention and should not be taken as limiting the scope of the invention. Rather, the scope of the invention is defined by the following claims. We therefore claim as our invention all that comes within the scope and spirit of these claims.

We claim:

1. A contactless electric meter sensor, comprising:
an annular member configured to be disposed around an electric meter; and
one or more magnetic field sensors mounted on the annular member; wherein
the one or more magnetic field sensors are configured to sense one or more magnetic fields generated by one or more current-carrying conductors passing through the electric meter.

2. The contactless electric meter sensor of claim 1, wherein the one or more magnetic field sensors comprise at least one of anisotropic magnetoresistive sensors, geometrical magnetoresistive sensors, and Hall Effect sensors.

3. The electric meter sensor of claim 1, further comprising one or more voltage sensors mounted on the annular member.

4. The electric meter sensor of claim 3, wherein the one or more voltage sensors are contactless voltage sensors comprising at least one of capacitively-coupled sensors and varactor sensors.

5. The electric meter sensor of claim 1, further comprising a tunneling magnetoresistive sensor mounted to the annular member.

6. The electric meter sensor of claim 1, further comprising a geometric magnetoresistive sensor mounted to the annular member.

7. The electric meter sensor of claim 1, further comprising a magnetic field flux concentrator mounted to the annular member.

8. The electric meter sensor of claim 1, wherein the annular member is an elastic strap.

9. The electric meter sensor of claim 1, further comprising a clamp for clamping the electric meter sensor around the electric meter.

10. The electric meter sensor of claim 1, further comprising a spirit level mounted to the annular member.

11. The electric meter sensor of claim 1, wherein the one or more magnetic field sensors are configured to sense a strength of the one or more magnetic fields at a frequency of from about 40 Hz to about 8,000 Hz.

12. A method of measuring electric power usage, comprising:
positioning a contactless electric meter sensor around the exterior of an electric meter, the contactless electric meter sensor comprising one or more magnetic field sensors mounted on an annular member;
sensing the strength of one or more magnetic fields generated by one or more current-carrying conductors located within the electric meter;
calculating the electric power flowing through the electric meter based at least in part on the strength of the one or more magnetic fields.

13. The method of claim 12, wherein positioning the contactless electric meter sensor further comprises positioning the contactless electric meter sensor such that each of the one or more magnetic field sensors is located a predetermined distance from the respective one or more current-carrying conductors.

14. The method of claim 12, wherein sensing the strength of the one or more magnetic fields further comprises sampling the strength of the one or more magnetic fields at from about 40 Hz to about 8,000 Hz.

15. The method of claim 12, further comprising transmitting the calculated electric power to a remote device for viewing by a user.

16. The method of claim 12, wherein calculating the electric power further comprises:
determining a current value based on the strength of the one or more magnetic fields; and
calculating the electric power based on the current value and a nominal line voltage of the one or more current-carrying conductors.

17. A system for measuring power usage at an electric meter, comprising:
an annular member disposed around the electric meter;
one or more magnetic field sensors mounted on the annular member; and
a signal processing module in communication with the one or more magnetic field sensors.

18. The system of claim 17, further comprising one or more voltage sensors mounted on the annular member.

19. The system of claim 17, wherein the signal processing module is configured to calculate a value of the electric power passing through the electric meter based at least in part on magnetic field strength measurements provided by the one or more magnetic field sensors.

20. The system of claim 19, further comprising an electronic device in communication with the signal processing module, the electronic device being configured to display the calculated electric power value to a user.
